(19) United States
(12) Patent Application Publication
(10) Pub. No.: US 2015/0017745 A1
(43) Pub. Date: Jan. 15, 2015

(54) POLISHING METHOD AND POLISHING APPARATUS

(71) Applicant: EBARA CORPORATION, Tokyo (JP)

(72) Inventors: Toshifumi KIMBA, Tokyo (JP); Keita YAGI, Tokyo (JP)

(21) Appl. No.: 14/323,771

(22) Filed: Jul. 3, 2014

(30) Foreign Application Priority Data
Jul. 8, 2013 (JP) 2013-142855

(51) Int. Cl. H01L 21/306; B24B 37/04; B24B 37/005; H01L 21/66; H01L 21/67

(52) U.S. Cl. CPC H01L 21/30625; H01L 22/12; H01L 22/20; H01L 21/67092; B24B 37/005; B24B 37/04
USPC 438/8; 451/1

(57) ABSTRACT

A polishing method capable of preventing damage to a substrate is disclosed. The polishing method includes inspecting a periphery of a substrate for an abnormal portion, polishing the substrate if the abnormal portion is not detected, and not polishing the substrate if the abnormal portion is detected. The abnormal portion of the substrate may be an foreign matter, such as an adhesive, attached to the periphery of the substrate. After polishing of the substrate, the periphery of the substrate may be inspected again for an abnormal portion.

### CROSS REFERENCE TO RELATED APPLICATION

This application claims priority to Japanese Patent Application No. 2013-142855 filed Jul. 8, 2013, the entire contents of which are hereby incorporated by reference.

### BACKGROUND

Semiconductor devices are fabricated through several processes including a process of polishing a dielectric film, e.g., SiO₂, and a process of polishing a metal film, e.g., copper or tungsten. A fabrication process of backside illumination CMOS sensor includes a process of polishing a silicon layer (or silicon wafer), in addition to the polishing processes of the dielectric film and the metal film. The backside illumination CMOS sensor is an image sensor using BSI (backside illumination) technique and has a light-receiving surface constituted by the silicon layer. A fabrication process of through-silicon via (TSV) also includes a process of polishing a silicon layer. The through silicon via is an electrode constructed by metal, such as copper, formed in a hole passing through the silicon layer.

The BSI process and the TSV process often use an SOI (Silicon on Insulator) substrate. This SOI substrate is fabricated by bonding a device substrate to a silicon substrate. More specifically, as shown in FIGS. 10A and 10B, a device substrate W1 and a silicon substrate W2 are bonded together with an adhesive. The back surface of the device substrate W1 is ground by a grinder, so that an SOI substrate, having a multilayer structure containing a silicon layer and a device layer as shown in FIG. 10C, is obtained. Further, as shown in FIG. 10D, an edge portion of the device layer may be removed by a polishing operation.

The SOI substrate that has been fabricated in this manner is transported to a CMP apparatus, where the silicon layer of the SOI substrate is polished. Specifically, the SOI substrate is placed in contact with a polishing pad while slurry is supplied onto the polishing pad, so that the silicon layer is polished.

The adhesive that is used in the fabrication process of the SOI substrate may be exposed on a periphery of the SOI substrate. Further, the SOI substrate may crack or a part of the silicon layer may peel off. Existence of such an abnormal portion in the SOI substrate may adversely affect polishing of the SOI substrate. For example, the exposed adhesive may be attached to the polishing pad, thereby causing cracking of the SOI substrate.

### SUMMARY OF THE INVENTION

It is an object to provide a polishing method and a polishing apparatus capable of preventing damage to a substrate.

Embodiments, which will be described below, rebate to a method and an apparatus for polishing a substrate, such as a wafer.

In an embodiment, there is provided a polishing method comprising: inspecting a periphery of a substrate for an abnormal portion; polishing the substrate if the abnormal portion is not detected; and not polishing the substrate if the abnormal portion is detected.

In an embodiment, the polishing method further comprises: after polishing of the substrate, inspecting the periphery of the substrate again for an abnormal portion.

In an embodiment, the polishing method further comprises: not starring polishing of a subsequent substrate if the abnormal portion is detected in the periphery of the polished substrate.

In an embodiment, the polishing method further comprises: changing polishing conditions for a subsequent substrate if the abnormal portion is detected in the periphery of the polished substrate.

In an embodiment, inspecting the periphery of the substrate for an abnormal portion comprises obtaining an image of the periphery of the substrate and inspecting the periphery of the substrate for an abnormal portion based on the image.

In an embodiment, inspecting the periphery of the substrate for an abnormal portion based on the image comprises inspecting the periphery of the substrate for an abnormal portion by comparing an index value, which indicates a characteristic of the abnormal portion appearing on the image, with a predetermined threshold value.

In an embodiment, the index value represents one of a size, a length, a shape, and a shade of color of the abnormal portion.

In an embodiment, the polishing method further comprises: not starting polishing of a subsequent substrate if the number of substrates, each having the abnormal portion, per one group consisting of a plurality of substrates has reached a set value.

In an embodiment, the substrate is a SOL substrate fabricated by bonding a device substrate to a silicon substrate.

In an embodiment, the abnormal portion is a foreign matter attached to an exposed surface of the SOI substrate, or a portion of a silicon layer that has peeled off.

In an embodiment, there is provided a polishing method comprising: polishing a substrate; once stopping polishing of the substrate and inspecting a periphery of the substrate for an abnormal portion; polishing the substrate again if the abnormal portion is not detected; and terminating polishing of the substrate if the abnormal portion is detected.

In an embodiment, there is provided a polishing apparatus comprising; an inspection unit configured to inspect a periphery of a substrate for an abnormal portion; a polishing unit configured to polish the substrate; a substrate transporting unit configured to transport the substrate between the inspection unit and the polishing unit; and an operation controller configured to control operations of the inspection unit, the polishing unit, and the substrate transporting unit, wherein the substrate transporting unit is operable to transport the substrate to the polishing unit if the abnormal portion is not detected, while not transporting the substrate to the polishing unit if the abnormal portion is detected.

In an embodiment, there is provided a polishing apparatus comprising: an inspection unit configured to inspect a periphery of a substrate for an abnormal portion; a polishing unit configured to polish the substrate; a substrate transporting unit configured to transport the substrate between the inspection unit and the polishing unit; and an operation controller configured to control operations of the inspection unit, the polishing unit, and the substrate transporting unit such that the polishing unit starts polishing of the substrate and then once stops polishing of the substrate, the substrate transporting unit then transports the substrate to the inspection unit that inspects the periphery of the substrate for an abnormal portion, and the substrate transporting unit transports the substrate to the polishing unit if the abnormal portion is not detected, while not transporting the substrate to the polishing unit if the abnormal portion is detected.

According to the above-discussed embodiments, the presence or absence of the abnormal portion, such as an exposed adhesive attached to the periphery of the substrate, is inspected prior to polishing of the substrate. Therefore, it is possible to prevent damage to the substrate that can be caused by the existence of the abnormal portion when polishing the substrate.

According to the above-discussed embodiments, the presence or absence of the abnormal portion, such as an exposed adhesive attached to the periphery of the substrate, is inspected before polishing of the substrate is completed. Therefore, it is possible to prevent damage to the substrate that can be caused by the existence of the abnormal portion when polishing the substrate.

### BRIEF DESCRIPTION OF THE DRAWINGS

FIG. 1 is a schematic view of a polishing apparatus which can perform a polishing method according to an embodiment;

FIG. 2 is a schematic view of a CMP unit shown in FIG. 1;

FIG. 3 is a schematic view of an inspection unit;

FIG. 4 is a view showing an example of image-taking positions of a wafer according to a step-and-repeat method;

FIG. 5 is a flowchart showing an operation sequence of the step-and-repeat method;

FIG. 6 is a flowchart of an embodiment illustrating a flow of processing a wafer;

FIG. 7 is a flowchart of another embodiment illustrating a flow of processing a wafer;

FIG. 8 is a plan view of a polishing apparatus according to an embodiment in which a substrate inspection device is incorporated in a substrate transporting unit;

FIG. 9 is a perspective view of the polishing apparatus shown in FIG. 8; and FIG. 10A, FIG. 103, FIG. 10C, and FIG. 10D are views illustrating a fabrication process of an SOI substrate.

### DETAILED DESCRIPTION OF EMBODIMENTS

Embodiments will be described below with reference to the drawings.

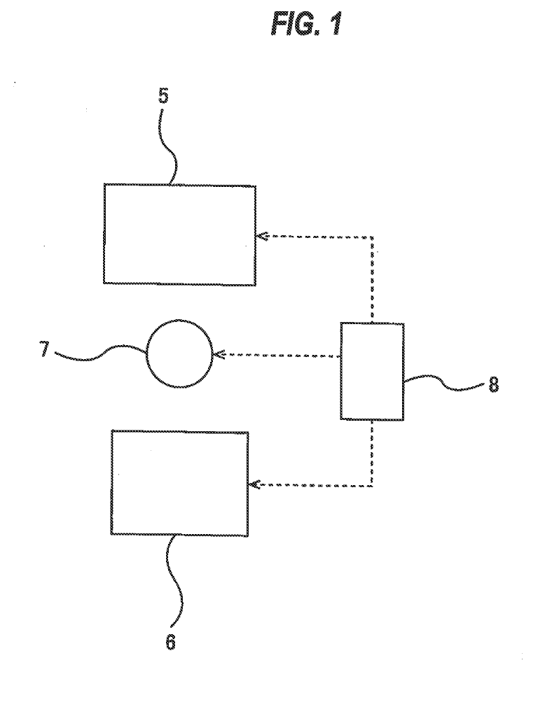

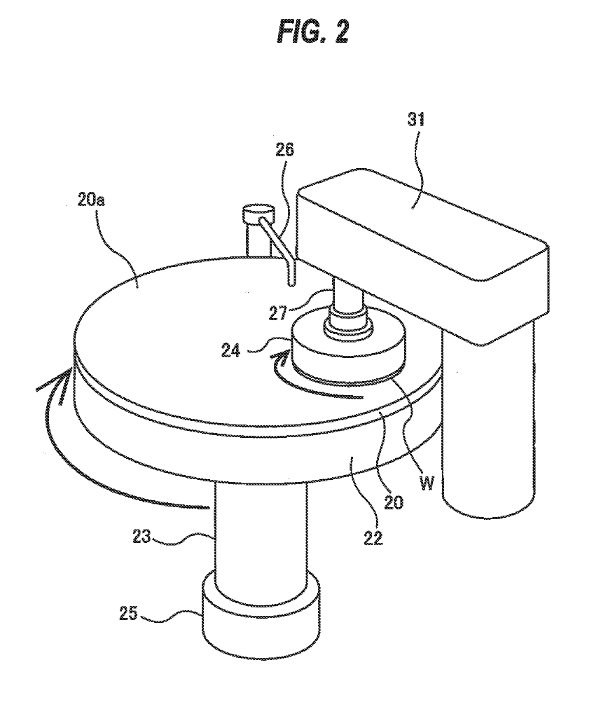

FIG. 1 is a schematic view of a polishing apparatus which can perform a polishing method according to an embodiment. This polishing method can be suitably applied to polishing of a SOI substrate which is fabricated by bonding a device substrate and a silicon substrate to each other as shown in FIGS. 10A through 10D.

As shown in FIG. 1, the polishing apparatus includes a CMP unit (i.e., a polishing unit) 5 for polishing a wafer which is an example of a substrate, an inspecting unit 6 for inspecting a periphery of the wafer for an abnormal portion in the periphery, a substrate transporting unit 7 for transporting the wafer between the CMP unit 5 and the inspection unit 6, and an operation controller 8 for controlling operations of the CMP unit 5, the inspection unit 6, and the substrate transporting unit 7.

FIG. 2 is a schematic perspective view showing the CMP unit 5 shown in FIG. 1. As shown in FIG. 2, the CMP unit 5 includes a polishing table 22 supporting a polishing pad 20, a top ring (or a polishing head) 24 for pressing a wafer W against the polishing pad 20, and a polishing liquid supply nozzle to 26 for supplying a polishing liquid (or slurry) onto the polishing pad 20.

The polishing table 22 is coupled via a table shaft 23 to a table motor 25 disposed below the polishing table 22, so that the polishing table 22 is rotated by the table motor 25 in a direction indicated by arrow. The polishing pad 20 is attached to an upper surface of the polishing table 22. The polishing pad 20 has an upper surface, which provides a polishing surface 20a for polishing the wafer W. The top ring 24 is secured to a lower end of a top ring shaft 27. The top ring 24 is configured to be able to hold the wafer W on its lower surface by vacuum suction. The top ring shaft 27 is coupled to a rotating device (not shown) disposed in a top ring arm 31, so that the top ring 24 is rotated by the rotating device through the top ring shaft 27.

Polishing of the surface of the wafer W is performed as follows. The top ring 24 and the polishing table 22 are rotated in respective directions indicated by arrows, and the polishing liquid (e.g., the slurry) is supplied from the polishing liquid supply nozzle 26 onto the polishing pad 20. In this state, the wafer W is pressed against the polishing surface 20a of the polishing pad 20 by the top ring 24. The surface of the wafer W is polished by a mechanical action of abrasive grains contained in the polishing liquid and a chemical action of a chemical component contained in the polishing liquid.

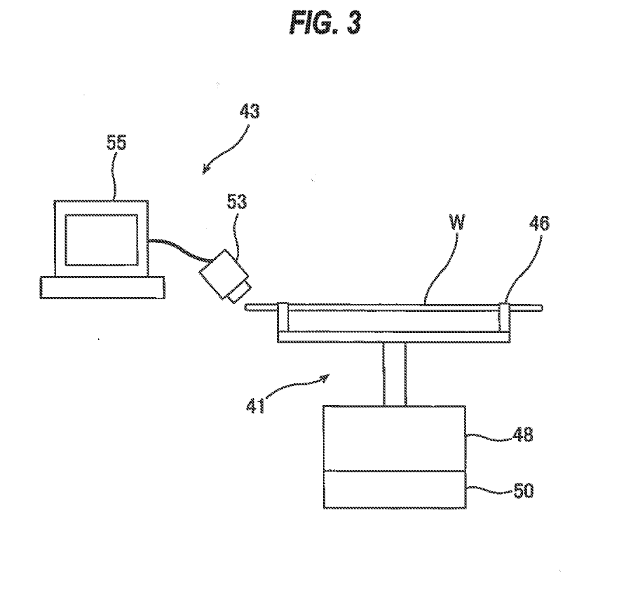

FIG. 3 is a schematic view showing the inspection unit 6. This inspection unit 6 is a device for detecting an abnormal portion in the periphery of the wafer W. As shown in FIG. 3, the inspection unit 6 includes a substrate holder 41 and a substrate inspection device 43. The substrate holder 41 has a plurality of chucks 46 for gripping the periphery of the wafer W, a step motor 48 for rotating the wafer W about its own axis through the chucks 46, and a rotary encoder (or a position detector) 50 for detecting a rotational angle of the wafer W.

The substrate inspection device 43 is configured to obtain an image (or a picture) of the periphery of the wafer W and inspect the wafer W for an abnormal portion based on the image. More specifically, the substrate inspection device 43 has an imaging camera 53 for taking an image (or a picture) of the periphery of the wafer W, and an image processor 55 for analyzing the image taken by the imaging camera 53. The imaging camera 53 is coupled to the image processor 55 so that the image, taken by the imaging camera 53, is transmitted to the image processor 55.

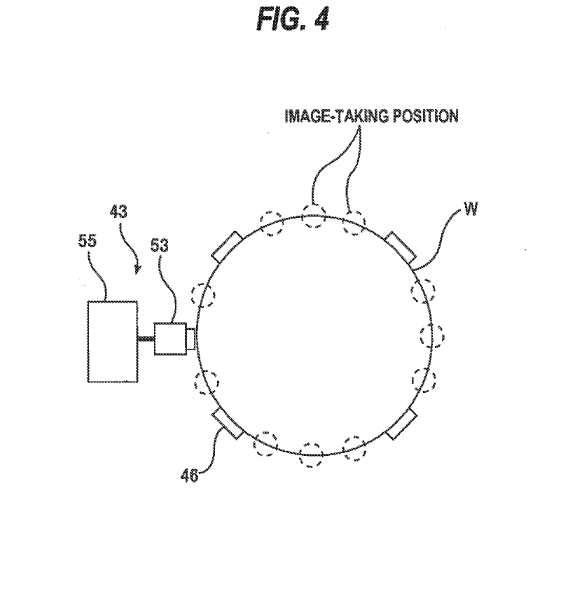

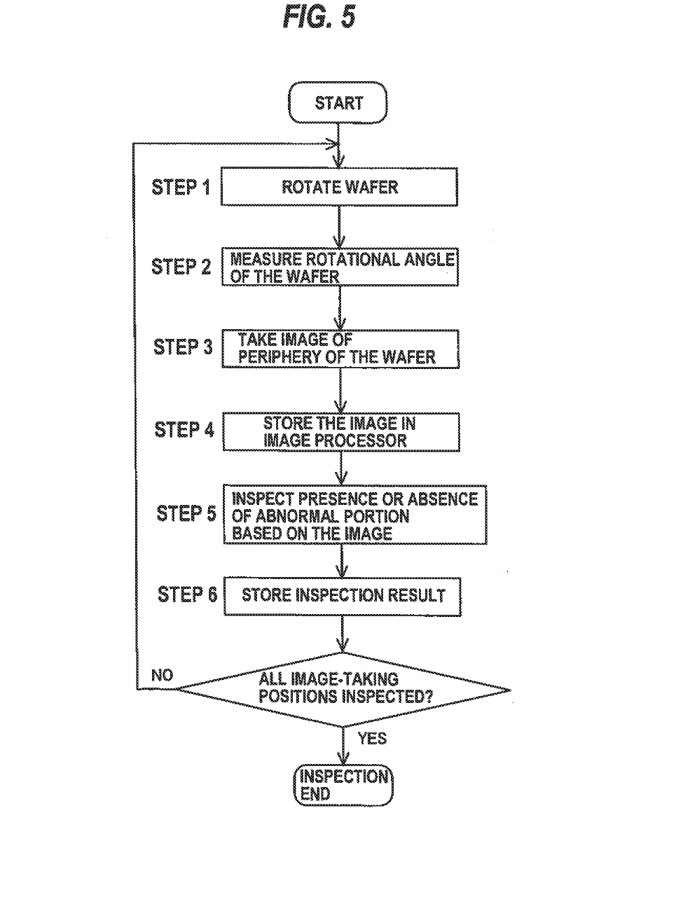

The inspection unit 6 is of a step-and-repeat type that takes a still image (or a static image) of the periphery of the wafer W while rotating the wafer W intermittently. FIG. 4 is a view showing an example of image-taking positions of the wafer W according to a step-and-repeat method, and FIG. 5 is a flowchart showing an operation sequence of the step-and-repeat method. As shown in FIG. 4, a plurality of image taking positions on the periphery of the wafer W are preset.

The image processor 55 transmits a command signal to the step motor 48, so that the step motor 48 rotates the wafer W (step 1). The rotational angle of the wafer W is measured by the rotary encoder 50 (step 2). When the rotating wafer W reaches a predetermined image-taking position, the rotation of the wafer W is stopped. Then, the imaging camera 53 takes an image of the periphery of the wafer W (step 3). The rotation of the wafer W and the stop of the rotation are repeated in the same manner, while still images of the periphery of the wafer w are obtained. The images obtained are transmitted to the image processor 55 and stored in a memory (i.e., a storage device) of the image processor 55 (step 4).

The image processor 55 inspects the periphery of the wafer W to determine whether an abnormal portion is present or absent based on the images of the periphery of the wafer W (step 5). A known image-processing technique, such as image processing for recognizing a figure on an image, or image processing for recognizing color on an image, can be used as the image processing for inspecting the presence or absence of the abnormal portion. Examples of the abnormal portion of the wafer W include a crack in the wafer W, a portion of a silicon layer (see FIG. 10C and FIG. 10D) that has peeled off, a foreign matter, such as an adhesive or particles, attached to an exposed surface of the wafer W, and a displaced portion of the silicon layer.

All of the images obtained are stored in the memory of the image processor 55. Each image is associated with a corresponding rotational angle of the wafer W and is stored in the image processor 55. The rotational angle indicating the position at which the image was taken is transmitted from the rotary encoder 50 to the image processor 55, and this rotational angle is stored in the memory together with the corresponding image. Therefore, information about the position of the abnormal portion of the wafer W, in addition to size (or area) and type (e.g., a crack or an adhesive) of the abnormal portion, can be obtained from the image taken by the imaging camera. The image processor 55 is coupled to the operation controller 8 shown in FIG. 1, and a detection signal indicating as to whether the abnormal portion of the wafer W is detected or not is transmitted from the image processor 55 to the operation controller 8.

The image processor 55 is configured to determine whether or not the abnormal portion exists in the periphery of the wafer W by comparing an index value, which indicates a characteristic of the abnormal portion that appears on the image, with a predetermined threshold value. More specifically, the image processor 55 determines the existence of the abnormal portion if the index value exceeds the predetermined threshold value. The index value indicating the characteristic of the abnormal portion may represent a size (or an area), a length, a shape, or a shade of color of the abnormal portion.

The image processor 55 stores, in its memory, an inspection result including the number of abnormal portions detected, the position, the index value (e.g., the size), and the type of each abnormal portion (step 6). The above-described steps from the rotating of the wafer W (step 1) to the storing of the inspection result (step 6) are repeated until the inspection is completed at all of the image-taking positions. The image-taking positions may be set only in part of the periphery of the wafer W, or may be set over the entire circumference of the wafer W. From the viewpoint of reliability of the inspection result, it is preferable to set the image-taking positions over the entire circumference of the wafer W. The image processor 55 is further configured to output the stored inspection result as inspection-result data, which can be used for analyzing conditions of the polishing apparatus.

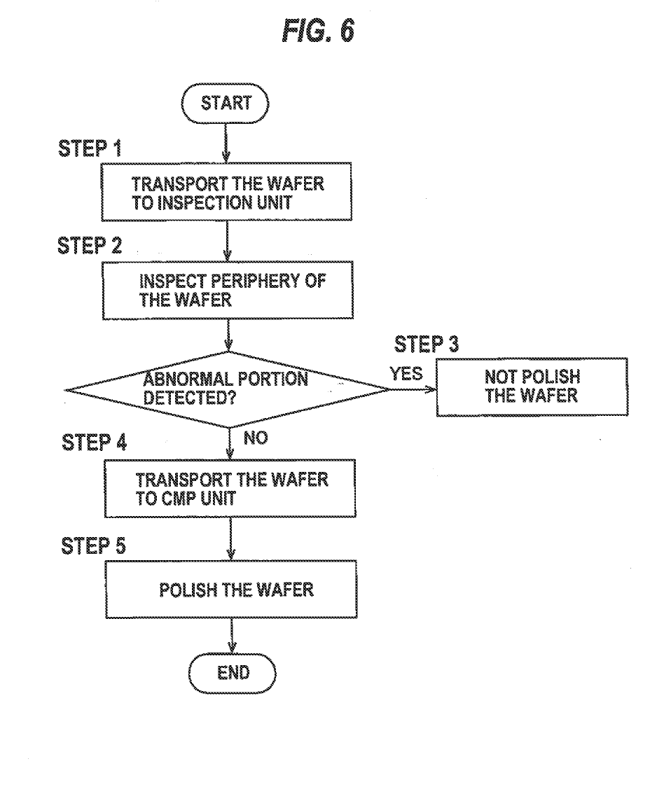

Next, a processing flow of the wafer W will be described with reference to a flowchart shown in FIG. 6. The wafer W is transported to the inspection unit 6 by the substrate transporting unit 7 before the wafer W is polished (step 1). The substrate inspection device 43 of the inspection unit 6 obtains the image of the periphery of the wafer W as discussed above, and inspects the image to determine whether the abnormal portion is present or not in the wafer W (step 2). If the substrate inspection device 43 detects the abnormal portion of the wafer W, the substrate transporting unit 7 does not transport the wafer W to the CMP unit 5 and as a result the wafer W is not polished (step 3).

The wafer W having the abnormal portion is returned to a substrate cassette (not shown) by the substrate transporting unit 7. The substrate cassette is a container that is used when a plurality of wafers are introduced into the polishing apparatus. The wafer W having the abnormal portion may be returned to the substrate cassette via a cleaning section (which will be described later) without performing cleaning of the wafer W. Alternatively, the wafer W having the abnormal portion may be returned directly to the substrate cassette without passing through the cleaning section.

If the substrate inspection device 43 did not detect the abnormal portion of the wafer W, the wafer W is transported to the CMP unit 5 by the substrate transporting unit 7 (step 4), and the surface of the wafer W is then polished (step 5).

After being polished by the CMP unit 5, the wafer W may be transported to the inspection unit 6 again by the substrate transporting unit 7. The inspection unit 6 takes an image of the periphery of the polished wafer W and inspects the wafer W again to determine whether or not the abnormal portion exits based on the image. If the abnormal portion of the wafer W is detected, polishing conditions for a subsequent wafer may be changed. For example, a rotational speed of the polishing table 22, a rotational speed of the top ring 24, a pressure applied from the top ring 24 to the wafer W to press the wafer W against the polishing pad 20, and other conditions may be changed based on the detection result of the abnormal portion. If the abnormal portion is detected in the polished wafer W, the CMP unit (or the polishing unit) 5 may not start the polishing operation of a subsequent wafer. The polishing conditions of the subsequent wafer may be changed based on a result of the comparison between an image obtained before polishing of a wafer W (including the rotational angle of the wafer W indicating a position at which the image was taken) and an image obtained after polishing of the wafer W (including the rotational angle of the wafer W indicating a position at which the image was taken).

According to the above-discussed embodiment, the presence or absence of the abnormal portion of the wafer W is inspected before polishing of the wafer W. Therefore, it is possible to prevent damage to the wafer that can be caused by the existence of the abnormal portion when polishing the wafer.

The inspection unit 6 may transmit the obtained image (including the rotational angle of the wafer W indicating a position at which the image was taken) to a host computer (not shown), which may inspect the presence or absence of the abnormal portion and may transmit to the operation controller 8 a command signal for stopping polishing of a wafer or a command signal for stopping introduction of a new wafer to the polishing apparatus. Further, the host computer may produce a polishing recipe containing polishing conditions that are modified based on the inspection result, and may transmit the polishing recipe to the operation controller 8. The host computer may transmit the modified polishing recipe to another polishing apparatus. Further, the host computer may analyze the obtained image (including the rotational angle of the wafer W indicating a position at which the image was taken), may modify processing conditions for a preceding process (e.g., a process of polishing a bevel portion or a periphery of a wafer) that is performed prior to CMP (chemical mechanical polishing), and may transmit a processing recipe, containing the modified processing conditions, to a processing apparatus (e.g., a bevel polishing apparatus) that performs the preceding process.

If the number of wafers, each containing the abnormal portion, per one group consisting of a plurality of wafers has reached a set value, it is preferable that the CMP unit (polishing unit) 5 does not start polishing of a subsequent wafer. If the number of wafers, each containing the abnormal portion, has reached the set value when the CMP unit 5 is just polishing a wafer, the CMP unit 5 may stop polishing of this wafer, or may complete polishing of this wafer according to a polishing recipe.

If the abnormal portion of the wafer is detected, it is preferable to check a condition of each of consumables of the polishing apparatus (e.g., a defect of the top ring 24, wear of the polishing pad 20) or check a condition of the cleaning section which will be described later.

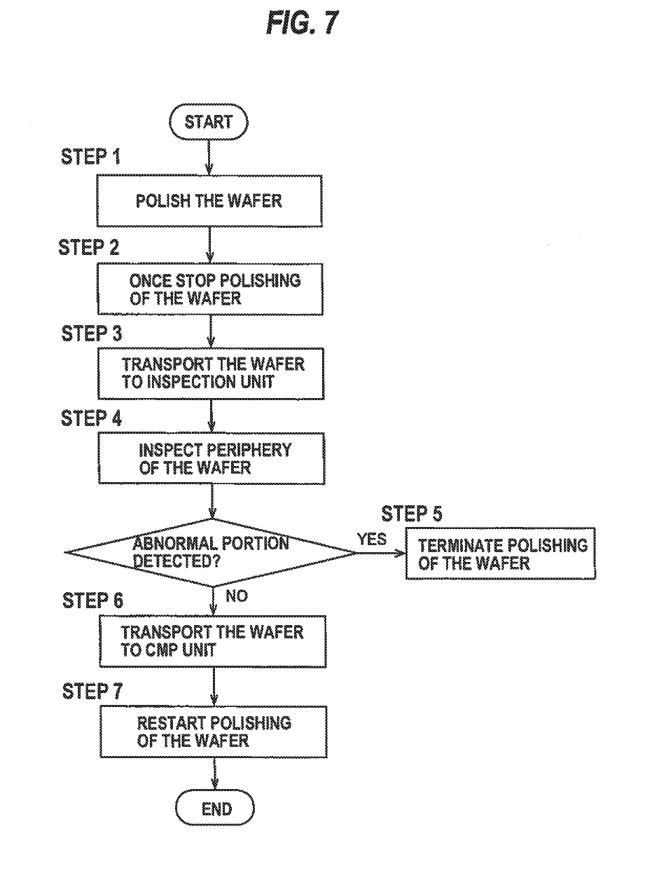

FIG. 7 is a flowchart of another embodiment of the polishing method. Operations and steps of this embodiment, which will not be described particularly, are identical to those of the above-discussed embodiment, and repetitive descriptions thereof are omitted. As shown in FIG. 7, the inspection of the wafer W may be performed during polishing of the wafer W. Specifically, the wafer W is polished (step 1), and polishing of the wafer W is once stopped (step 2). The wafer W is then transported to the inspection unit 6 by the substrate transporting unit 7 (step 3), and the inspection unit 6 inspects the periphery of the wafer W for the abnormal portion (step 4). If the abnormal portion is detected, polishing of the wafer W is not started again, and polishing of the wafer W is terminated (step 5). If the abnormal portion is not detected, the wafer W is transported to the CMP unit 5 by the substrate transporting unit 7 (step 6), the polishing of the wafer W may be started again (step 7). In this embodiment also, the presence or absence of the abnormal portion of the wafer W is inspected before polishing of the wafer W is completed. Therefore, it is possible to prevent damage to the wafer that can be caused by the existence of the abnormal portion when polishing the wafer.

Depending on the type of the abnormal portion, a processing flow after the wafer inspection may be changed. For example, if the abnormal portion is a relatively serious defect (e.g., crack of the wafer), polishing of the wafer W may not be started again. If the abnormal portion is a relatively slight defect (e.g., an adhesive attached to the wafer W), polishing of the wafer W may be started again.

The above-described inspection unit 6 has one imaging camera 53 for taking an image (or a picture) from above the periphery of the wafer W. In another embodiment, the inspection unit 6 may have a plurality of imaging cameras. For example multiple imaging cameras may be disposed above, beside, and below the periphery of the wafer W. The inspection unit 6 may be of light-scattering type, instead of the above-described image-processing type. The inspection unit 6 of the light-scattering type is configured to direct a laser beam at the periphery of the wafer W and detect the existence of the abnormal portion based on an intensity of the reflected laser beam. Such inspection unit 6 of the light-scattering type may use a known technique as disclosed in Japanese laid-open patent publication No. 2010-10234.

The above-described inspection unit 6 is of a stand-alone type. Instead, the inspection unit 6 may be incorporated in a unit that has been already installed in the polishing apparatus. For example, the above-described substrate inspection device 43 may be incorporated in a substrate transporting mechanism, a film-thickness measuring unit, a substrate-cleaning unit, or a substrate-drying unit.

In the above-discussed embodiments, the CMP unit 5 for chemically mechanically polishing a wafer in the presence of the slurry is used as the polishing unit for polishing a surface of a wafer. Instead of the CMP unit 5 shown in FIG. 1, a grinding unit may be used as the polishing unit. The grinding unit is configured to bring the wafer into sliding contact with a whetstone (or a fixed abrasive) while supplying pure water, as the polishing liquid, onto the whetstone to thereby polish for grind) the wafer. For example, the inspection unit 6 may inspect a periphery of a silicon substrate W2 shown in FIG. 10B for an abnormal portion, and if the abnormal portion is not detected, the grinding unit (i.e., the polishing unit) may polish (or grind) a back side surface of a device substrate W1, as shown in FIG. 10C.

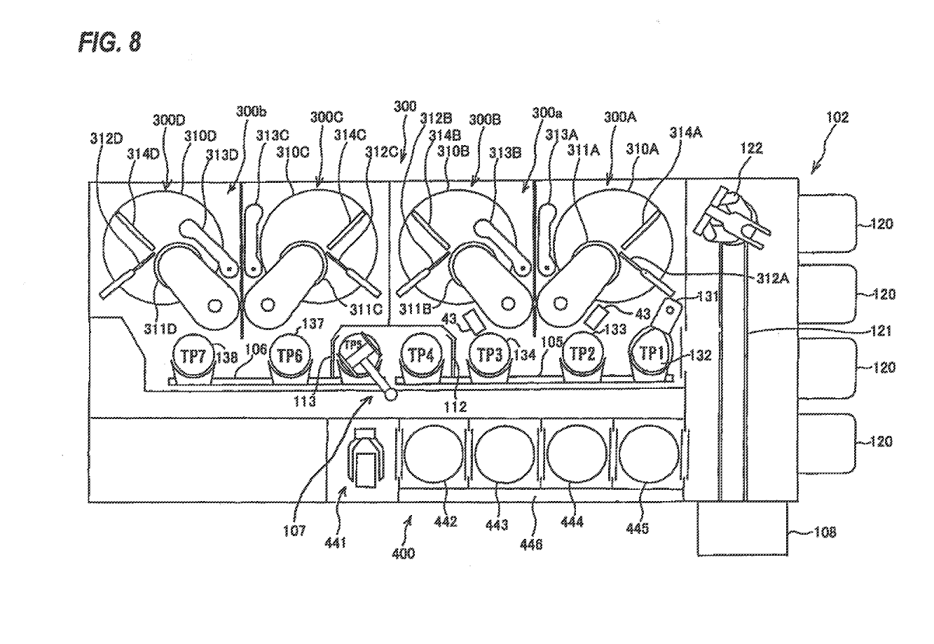

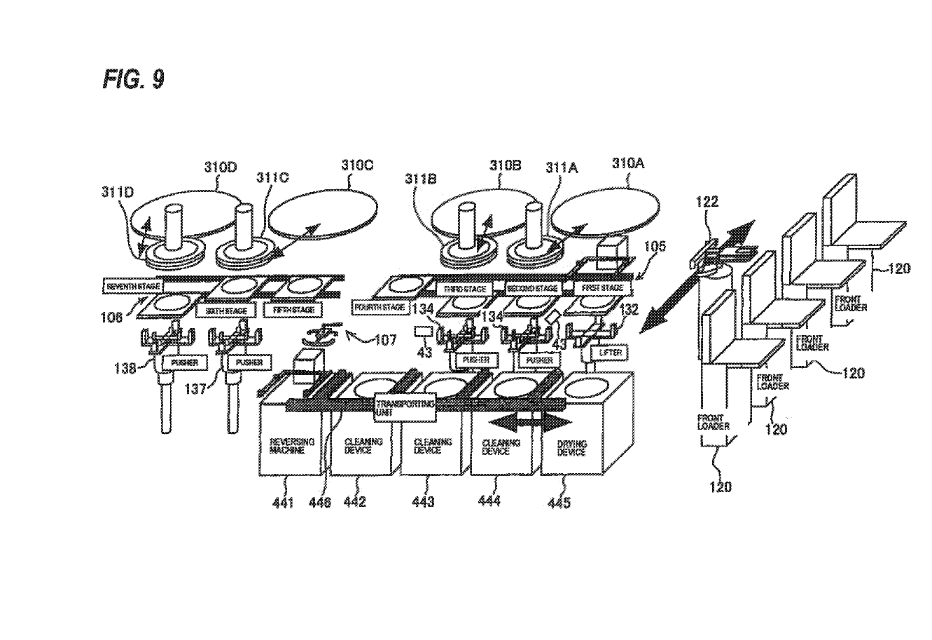

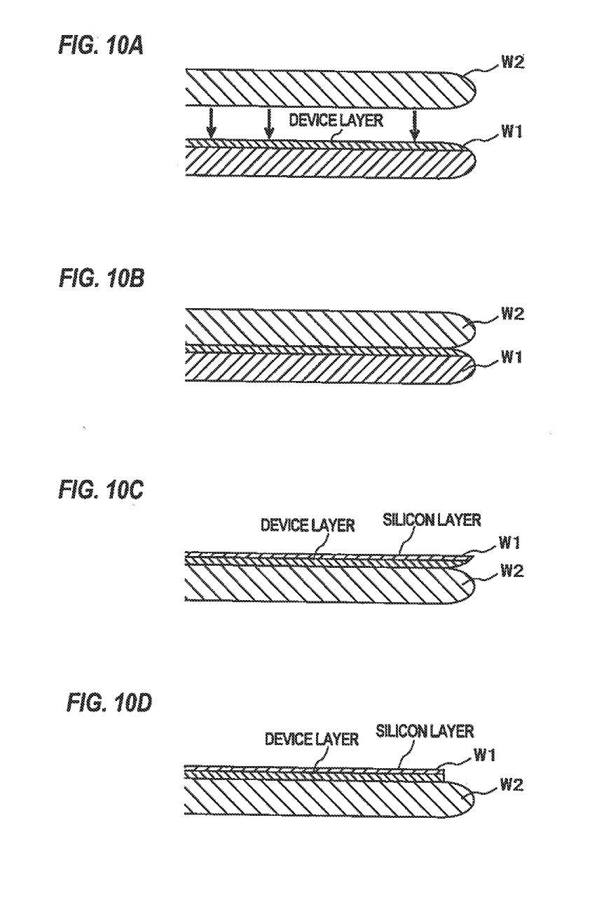

FIG. 8 is a plan view of a polishing apparatus according to an embodiment in which the substrate inspection device 43 is incorporated in a substrate transporting mechanism, and FIG. 9 is a perspective view of the polishing apparatus shown in FIG. 8. The polishing apparatus includes a loading and unloading section 102, a polishing section 300 (300a, 300b) for polishing a wafer, and a cleaning section 400 for cleaning the polished wafer.

The loading and unloading section 102 has four front loaders 120 on which wafer cassettes (or substrate cassettes), each storing a plurality of wafers therein, are placed. A moving mechanism 121, extending along an arrangement direction of the front loaders 120, is provided in the loading and unloading section 102. A transfer robot 122 is provided on the moving mechanism 121. This first transfer robot 122 is movable along the direction in which the wafer cassettes are arranged. The transfer robot 122 can access the wafer cassettes placed on the front loaders 120 by moving on the moving mechanism 121.

The polishing section 300 includes a first polishing section 300a having a first polishing unit 300A and a second polishing unit 300B therein, and a second polishing section 300b having a third polishing unit 3000 and a fourth polishing unit 30013 therein.

The first polishing unit 300A includes a polishing table 310A supporting a polishing pad thereon, a top ring 311A for holding a wafer and pressing the wafer against the polishing pad on the polishing table 310A, a polishing liquid supply nozzle 312A for supplying a polishing liquid or a dressing liquid (e.g., pure water) onto the polishing pad, a dresser 313A for dressing the polishing pad, and an atomizer 314A having nozzles for ejecting a mixture of a liquid (e.g., pure water) and a gas (e.g., nitrogen) or a liquid (e.g., pure water) in an atomized state to the polishing pad.

Similarly, the second polishing unit 300B includes a polishing table 310B, a top ring 311B, a polishing liquid supply nozzle 312B, a dresser 313B, and an atomizer 314B. The third polishing unit 300C includes a polishing table 310C, a top ring 3111, a polishing liquid supply nozzle 312C, a dresser 313C, and an atomizer 3140. The fourth polishing unit 3001) includes a polishing table 310D, a top ring 311D, a polishing liquid supply nozzle 3121), a dresser 313D, and an atomizer 314D.

A first linear transporter 105 is provided between the first polishing section 300a and the cleaning section 400. This first linear transporter 105 is configured to transport a wafer between four transferring positions, i.e., a first transferring position TP1, a second transferring position TP2, a third transferring position TP3, and a fourth transferring position TP4. A reversing machine 131 for reversing a wafer transferred from the first transfer robot 122 is disposed above the first transferring position TP1 of the first linear transporter 105. A vertically movable lifter 132 is disposed below the reversing machine 131. A vertically movable pusher 133 is disposed below the second transferring position TP2, and a vertically movable pusher 134 is disposed below the third transferring position TP3. A shutter 112 is provided between the third transferring position TP3 and the fourth transferring position TP4.

In the second polishing section 300b, a second linear transporter 106 is provided next to the first linear transporter 105. This second linear transporter 106 is configured to transport a wafer between three transferring positions, i.e., a fifth transferring position TP5, a sixth transferring position TP6, and a seventh transferring position TP7. A pusher 137 is disposed below the sixth transferring position TP6, and a pusher 138 is disposed below the seventh transferring position TP7. A shutter 113 is provided between the fifth transferring position TP5 and the sixth transferring position TP6.

The cleaning section 400 includes a reversing machine 441 for reversing a wafer, three cleaning devices 442, 443, 444 each for cleaning a polished wafer, a drying device 445 for drying the cleaned wafer, and a third linear transporter 446 for transporting a wafer between the reversing machine 441, the cleaning devices 442-444, and the drying unit 445. Each of the cleaning devices 442, 443, 444 is configured to clean the wafer with a cleaning tool in the presence of a cleaning liquid while rotating the wafer horizontally. The drying device 445 is configured to dry the cleaned wafer by rotating the cleaned wafer at high speed.

A swing transporter 107 for transporting a wafer between the first linear transporter 105, the second linear transporter 106, and the reversing machine 441 of the cleaning section 400 is disposed between the first linear transporter 105 and the second linear transporter 106. This swing transporter 107 is configured to transport the wafer from the fourth transfer position TP4 of the first linear transporter 105 to the fifth transfer position TP5 of the second linear transporter 106, from the fifth transfer position TP5 to the reversing machine 441, and from the fourth transfer position TP4 to the reversing machine 441.

The pusher 133 is configured to transfer a wafer on a transporting stage TS1 of the first linear transporter 105 to the top ring 311A of the first polishing unit 300A, and transfer a polished wafer in the first polishing unit 300A to a transporting stage TS2 of the first linear transporter 105. The pusher 134 is configured to transfer a wafer on the transporting stage TS2 of the first linear transporter 105 to the top ring 311B of the second polishing unit 300B, and transfer a polished wafer in the second polishing unit 300B to a transporting stage TS3 of the first linear transporter 105.

The pusher 137 is configured to transfer a wafer on a transporting stage TS5 of the second linear transporter 106 to the top ring 3110 of the third polishing unit 300C, and transfer a polished wafer in the third polishing unit 300C to a transporting stage TS6 of the second linear transporter 106. The pusher 138 is configured to transfer a wafer on a transporting stage TS6 of the second linear transporter 106 to the top ring 311D of the fourth polishing unit 3001, and transfer a polished wafer in the fourth polishing unit 300D to a transporting stage TS7 of the second linear transporter 106. In this manner the pushers 133, 134, 137, 138 serve as devices for transferring the wafer between the linear transporters 105, 106 and the top rings.

Substrate inspection devices 43 are disposed adjacent to the pushers 133, 134, respectively. These pushers 133, 134 have the same functions as the substrate holder 41 shown in FIG. 3, and are capable of holding the wafer and rotating the wafer by a predetermined angle. Therefore, each of the pushers 133, 134 serves not only as a part of the substrate transporting mechanism, but also as a part of the inspection unit 6 for inspecting the wafer for the abnormal portion.

The substrate inspection device 43 may be provided in a film-thickness measuring unit 108 shown in FIG. 8. For example, the film-thickness measuring unit 108 may have a substrate holder (not shown) having the same structure as the substrate holder 41 shown in FIG. 3, a film-thickness sensor for measuring a film thickness of the wafer, and the above-described substrate inspection device 43. In this case, the film-thickness measuring unit 108 has a function to inspect the wafer for the abnormal portion, in addition to a function to measure the film thickness of the wafer.

The substrate inspection device 43 may be provided in at least one of the cleaning devices 442, 443, 444. For example, the cleaning device 442 may have a substrate holder (not shown) having the same structure as the substrate holder 41 shown in FIG. 3, a cleaning tool (not shown) for cleaning the wafer, a cleaning nozzle (not shown) for supplying a cleaning liquid onto the wafer, and the above-described substrate inspection device 43. In this case, the cleaning device 442 has a function to inspect the wafer for the abnormal portion, in addition to a function to clean the wafer.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims and equivalents,

What is claimed is:

1. A polishing method, comprising:
inspecting a periphery of a substrate for an abnormal portion;
polishing the substrate if the abnormal portion is not detected; and
not polishing the substrate if the abnormal portion is detected.

2. The polishing method according to claim 1, further comprising:
after polishing of the substrate, inspecting the periphery of the substrate again for an abnormal portion.

3. The polishing method according to claim 2, further comprising:
not starting polishing of a subsequent substrate if the abnormal portion is detected in the periphery of the polished substrate.

4. The polishing method according to claim 2, further comprising:
changing polishing conditions for a subsequent substrate if the abnormal portion is detected in the periphery of the polished substrate.

5. The polishing method according to claim 1, wherein inspecting the periphery of the substrate for an abnormal portion comprises obtaining an image of the periphery of the substrate and inspecting the periphery of the substrate for an abnormal portion based on the image.

6. The polishing method according to claim 5, wherein inspecting the periphery of the substrate for an abnormal portion based on the image comprises inspecting the periphery of the substrate for an abnormal portion by comparing an index value, which indicates a characteristic of the abnormal portion appearing on the image, with a predetermined threshold value.

7. The polishing method according to claim 6, wherein the index value represents one of a size, a length, a shape, and a shade of color of the abnormal portion.

8. The polishing method according to claim 1, further comprising:
not starting polishing of a subsequent substrate if the number of substrates, each having the abnormal portion, per one group consisting of a plurality of substrates has reached a set value.

9. The polishing method according to claim 1, wherein the substrate is a SOI substrate fabricated by bonding a device substrate to a silicon substrate.

10. The polishing method according to claim 9, wherein the abnormal portion is a foreign matter attached to an exposed surface of the SOI substrate, or a portion of a silicon layer that has peeled off.

11. A polishing method, comprising:
polishing a substrate;
once stopping polishing of the substrate and inspecting a periphery of the substrate for an abnormal portion;
polishing the substrate again if the abnormal portion is not detected; and
terminating polishing of the substrate if the abnormal portion is detected.

12. The polishing method according to claim 11, further comprising:
after polishing of the substrate, inspecting the periphery of the substrate again for an abnormal portion.

13. The polishing method according to claim 12, further comprising:
not starting polishing of a subsequent substrate if the abnormal portion is detected in the periphery of the polished substrate.

14. The polishing method according to claim 12, further comprising:
changing polishing conditions for a subsequent substrate if the abnormal portion is detected in the periphery of the polished substrate.

15. The polishing method according to claim 11, wherein inspecting the periphery of the substrate for an abnormal portion comprises obtaining an image of the periphery of the substrate and inspecting the periphery of the substrate for an abnormal portion based on the image.

16. The polishing method according to claim 15, wherein inspecting the periphery of the substrate for an abnormal portion based on the image comprises inspecting the periphery of the substrate for an abnormal portion by comparing an index value, which indicates a characteristic of the abnormal portion appearing on the image, with a predetermined threshold value.

17. The polishing method according to claim 16, wherein the index value represents one of a size, a length, a shape, and a shade of color of the abnormal portion.

18. The polishing method according to claim 11, further comprising:
not starting polishing of a subsequent substrate if the number of substrates, each having the abnormal portion, per one group consisting of a plurality of substrates has reached a set value.

19. The polishing method according to claim 11, wherein the substrate is a SOI substrate fabricated by bonding a device substrate to a silicon substrate.

20. The polishing method according to claim 19, wherein the abnormal portion is a foreign matter attached to an exposed surface of the SOI substrate, or a portion of a silicon layer that has peeled off.

21. A polishing apparatus, comprising;
an inspection unit configured to inspect a periphery of a substrate for an abnormal portion;
a polishing unit configured to polish the substrate;
a substrate transporting unit configured to transport the substrate between the inspection unit and the polishing unit; and
an operation controller configured to control operations of the inspection unit, the polishing unit, and the substrate transporting unit,
wherein the substrate transporting unit is operable to transport the substrate to the polishing unit if the abnormal portion is not detected, while not transporting the substrate to the polishing unit if the abnormal portion is detected.

22. A polishing apparatus, comprising:
an inspection unit configured to inspect a periphery of a substrate for an abnormal portion;
a polishing unit configured to polish the substrate;
a substrate transporting unit configured to transport the substrate between the inspection unit and the polishing unit; and
an operation controller configured to control operations of the inspection unit, the polishing unit, and the substrate transporting unit such that the polishing unit starts polishing of the substrate and then once stops polishing of the substrate, the substrate transporting unit then transports the substrate to the inspection unit that inspects the periphery of the substrate for an abnormal portion, and the substrate transporting unit transports the substrate to the polishing unit if the abnormal portion is not detected, while not transporting the substrate to the polishing unit if the abnormal portion is detected.
